(19) United States
(12) Patent Application Publication
(10) Pub. No.: US 2011/0085310 A1
(43) Pub. Date: Apr. 14, 2011

(54) SPACE SAVING CIRCUIT BOARD

(76) Inventors: Joseph M. Cachia, Las Vegas, NV (US); Ken Segler, North Las Vegas, NV (US)

(21) Appl. No.: 12/577,117

(22) Filed: Oct. 9, 2009

(51) Int. Cl. H05K 1/18; H05K 3/00

(52) U.S. Cl. 361/764; 361/761; 29/846

(57) ABSTRACT

The present invention is a circuit board with precision clearance holes that accommodate components that are attached to the circuit board. The components are mounted in an inverted position so that the component contacts are still connected to the top side of the circuit board and the body of the component fits substantially within the precision clearance hole.

### FIELD OF THE INVENTION

This invention relates to a circuit board for computers, printers, and other electronic machines. More specifically a space saving circuit board with a precision hole cut into the board that accommodates a device, such as an integrated circuit chip.

### BACKGROUND

A circuit board (also known as a printed circuit board) is a self-contained module of interconnected electronic components found in such devices as radios, printers, cellular phones, and computers. The circuits are formed by a thin layer of conducting material deposited, printed, or remaining after board etching on the surface of a substrate. The substrate is typically called an insulating board. Electronic components, such as resistors, diodes, capacitors, transistors, and chips are placed on the surface of the substrate and soldered to the interconnecting circuits. Contact points, or fingers, along one or more edges of the substrate act as connectors to other circuit boards or to external electrical devices, such as an on-off switch.

There are essentially three types of printed circuit board construction: single-sided, double-sided, and multi-layered. Single-sided boards have the circuit and components on one side of the substrate. When the circuit complexity or the number of components becomes too much for a single-sided board, a double-sided board may be used. Electrical connections between the circuits on each side are made by drilling holes through the substrate in appropriate locations and plating the inside of the holes with a conducting material. The multi-layered board has a substrate made up of layers of printed circuits separated by layers of insulation. The components on the surface of the board connect through plated holes drilled down to the appropriate circuit layer. U.S. Pat. No. 4,967,314, issued to Higgins, III and U.S. Pat. No. 7,351,916, issued to Hsu provide examples of circuit board construction.

Components on a circuit board are electrically connected to the circuits by two different methods: 1) through hole technology; and 2) surface mount technology. Regarding through hole technology, each component has thin wires, or leads, which are pushed through small holes in the substrate and soldered to connection pads in the circuits on the opposite side and/or the same side as the component. Regarding surface mount technology, short J-shaped or L-shaped legs on each component contact the printed circuits directly.

Circuit boards are typically custom made for a particular product and must be designed to perform a specific function in the space allotted. The first step in board construction is to determine the board design. The purpose of the design stage is to layout the circuit pattern and determine where and how the components will be connected to the board. If necessary, contact holes are drilled in the board. Once the circuit pattern is laid out, the board is created and components are mounted to the board.

Currently, the most common method of circuit board construction consists of a flat thin board that has various electronic components directly soldered to one side of the board at precise locations to make the circuit complete. The resulting height of the assembly is the collective thicknesses of the board, its components, and the solder beads on the opposite side of the board.

This standard method of circuit board manufacture is frequently used to make replacement circuit boards for use in refurbishing spent or empty cartridges used in laser printers, copiers, faxes, and other types of office machines. In most applications, the spent Original Equipment Manufacturer's (OEM) circuit board is removed, and the replacement circuit boards are inserted or installed directly into the proper location and position on the cartridge. The replacement circuit typically must have identical size and shape as the OEM circuit board to achieve proper installation. This provides a fully functional and transparent change. In some applications, the OEM circuit board is embedded within the cartridge and removal for replacement is impossible without damaging the cartridge and rendering it useless.

The current solution to this problem is to place the replacement circuit board directly on the OEM board. The replacement board is thus in a position to make electrical connection with the contacts in the machine, and communicate as required. However, some machines have limited space available to accommodate the added thickness of the replacement circuit board, resulting in other issues such as: 1) failure of the cartridge to lock into place and maintain proper position and connection, which also may cause poor printer gear engagement (skipping or grinding of gear teeth) and toner leakage; and 2) failure of the machine door to properly latch, causing intermittent error messages, disruption in printing, and other inconvenience to the machine user.

As such, there is a need in the art for a circuit board, specifically a replacement printer circuit board, which is significantly thinner than the standard circuit board.

There are several references that disclose improved circuit boards with space-saving designs. U.S. Pat. No. 5,590,029, issued to Estes, discloses a surface mounted space-saving circuit board where a mounted device is installed in a vertical dielectric body rather than being directly mounted in a horizontal manner. Estes accomplishes the vertical mounting by providing a plated, electrically conductive hole in the board. Although Estes may provide some space saving benefit lengthwise or longitudinally, in no way does Estes reduce the thickness of the circuit board. In fact, Estes clearly discloses a circuit board that with an increased thickness. Furthermore, although Estes discloses a fitted hole for a vertical mounting device, the hole is similar to any other drilled hole because it is plated and thus part of the contiguous circuit.

Another space-saving circuit board is disclosed by U.S. Pat. No. 5,076,794, issued to Ganthier. Ganthier discloses a chip that is removably mounted to a circuit board through a series of underside mounting contact points. Although Ganthier discloses a way to make a circuit board slightly thinner, the overall thickness of the circuit board still comprises at least the combination of the thickness of the chip and the board. Additionally, Ganthier will not work with a standard surface mounted chip.

Thus, there is a need in the art for a space-saving circuit board wherein the board has precision clearance holes cut into the board that allows insertion of the mounted components. The resulting circuit board is significantly thinner than a circuit board using traditional methods to mount components.

### SUMMARY OF THE INVENTION

Various embodiments of the invention are directed towards overcoming the above deficiencies of the prior art by providing a space-saving circuit board with precise clearance holes cut into the board that accommodate mounted components.

One embodiment of the present invention is a space-saving circuit board comprising: a circuit board; a precision clearance hole; and a component. The component is comprised of a body and one or more contacts. The precision clearance hole is cut into the circuit board; and the body of the component is inserted into the precision clearance hole and the one or more contacts are affixed to the circuit board. Preferably a size and a shape of the precision clearance hole corresponds to a size and a shape of the component and the body of the component fits matingly with the precision clearance hole. Preferably the space-saving circuit board is a replacement circuit board for a printer.

In one embodiment of the invention the component is a surface mounted integrated circuit chip. The circuit board has a top side and a bottom side. The surface mounted integrated circuit chip is comprised of a body top side, a body bottom side, and one or more chip contacts. The surface mounted integrated circuit chip is preferably inverted before being inserted into the precision clearance hole such that the body top side of the surface mounted integrated circuit chip is facing a same direction as and is essentially parallel to a bottom side of the circuit board; and the chip contacts are affixed to the top side of the circuit board.

In another embodiment of the invention the space-saving circuit board has a plurality of precision clearance holes and a plurality of components. The plurality of components are inserted into the plurality of precision clearance holes. The size and shape of the plurality of precision clearance holes corresponds to a size and a shape of the plurality of components and the plurality of components fit matingly with the plurality of precision clearance holes. Preferably the space-saving circuit board is a replacement circuit board for a printer.

Another embodiment of the invention is a method of constructing a space-saving circuit board, the steps comprising: providing a circuit board; providing one or more components; wherein the one or more components are comprised of a body and one or more contacts; cutting one or more precision clearance holes into the circuit board such that the one or more components fit into the one or more precision clearance holes; inserting the one or more components into the one or more precision clearance holes; and affixing the one or more contacts to the circuit board. The components are preferably one or more surface mounted integrated circuit chips. The circuit board has a top side and a bottom side. The surface mounted integrated circuit chips have a body top, side, a body bottom side, and one or more chip contacts. The chip contacts are on a body bottom side of the one or more surface mounted integrated circuit chips. The one or more surface mounted integrated circuit chips are inverted before being inserted into the one or more precision clearance holes such that the body top side of the one or more surface mounted integrated circuit chips is facing a same direction as and is essentially parallel to a bottom side of the circuit board. The chip contacts are affixed to the top side of the circuit board.

Another embodiment of the present invention is a circuit board with components mounted in an inverted (or upside down) position. The components are inserted into precision cut holes, which accommodate the main body of the component. Preferably the component is still soldered directly to the circuit board on the upper surface of the board. However, the component can be connected to the bottom surface of a double-sided circuit board or to any contact point in a multi-layered circuit board without deviating from the scope of the invention.

Another embodiment of the invention is a method of manufacturing a circuit board with precision clearance holes and mounting various components in the precision clearance holes to reduce the final thickness of the circuit board.

An object of the present invention is to provide a space-saving circuit board that overcomes the deficiencies and limitations of the prior art.

Another object of the present invention is to provide a circuit board that is significantly thinner than a circuit board that is manufactured using current methods.

Another object of the present invention is to provide replacement circuit board that can be installed into and engage with printer cartridges in which the original equipment manufacturer circuit board cannot be removed.

Another object of the present invention is to provide a circuit board with precise clearance holes that are cut into the circuit board and accommodate various components, such as chips, capacitors, transistors, and resistors.

Other features and advantages are inherent in the improved circuit board claimed and disclosed will become apparent to those skilled in the art from the following detailed description and its accompanying drawings.

### BRIEF DESCRIPTION OF THE DRAWINGS

FIG. 1 is a detailed illustration of a perspective view of a prior art circuit board.

FIG. 2 is a detailed illustration of a perspective view of a circuit board component.

FIG. 3 is a detailed illustration of a side view of a circuit board component.

FIG. 4 is a detailed illustration of a perspective view of one embodiment of the present invention and shows a precision clearance hole.

FIG. 5 is a detailed illustration of a perspective view of one embodiment of the present invention and shows a component inserted into a precision clearance hole.

FIG. 6 is a detailed illustration of a perspective view of one embodiment of the present invention and shows two components inserted into two precision clearance holes.

FIG. 7 is a detailed illustration of a side view of a prior art circuit board.

FIG. 8 is a detailed illustration of a side view of one embodiment of the present invention and shows a component inserted into a precision clearance hole.

### DETAILED DESCRIPTION OF THE DRAWINGS

In the following detailed description of the various embodiments of the invention, numerous specific details are set forth in order to provide a thorough understanding of various embodiments of the invention. However, one or more embodiments of the invention may be practiced without these specific details. In other instances, well-known methods, procedures, and/or components have not been described in detail so as not to unnecessarily obscure aspects of embodiments of the invention.

In the following detailed description of the various embodiments of the invention, reference is made to the accompanying drawings that form a part hereof, and in which is shown by way of illustration a specific embodiment in which the invention may be practiced. It is to be understood that other embodiments may be utilized and structural changes may be made without departing from the scope of the present invention. Accordingly, the drawings and detailed description are to be regarded as illustrative in nature and not restrictive. In addition, the reference or non-reference to a particular embodiment of the invention shall not be interpreted to limit the scope of the invention.

In the following description, certain terminology is used to describe certain features of one or more embodiments of the invention. For instance “circuit board” or “printed circuit board” refers to any single-sided, double-sided, or multi-layered board that includes at least one conductive layer and at least one insulating or substrate layer. The circuit board preferably includes one or more attached components such as chips, transistors, and resistors. The components may be attached by any means, including but not limited to surface mounting or through hole attaching. “Precision clearance hole” refers to a precisely designed and measured hole cut in a circuit board. Preferably the hole is cut through the entire thickness of a circuit board, but not necessarily cut through all layers of a multi-layer board. A precision clearance hole is designed to accommodate a specific component mounted within a circuit board. “Component” refers to a device that is attached or connected, typically through soldering, to a circuit board. Examples of components include, but are not limited to integrated circuits, chips, resistors, capacitors, transistors, and diodes. “Printer” refers to any image forming device that accepts the use of an ink or toner cartridge, including, but not limited to printers, copiers, facsimiles, or machines that combine printing, copying, and faxing.

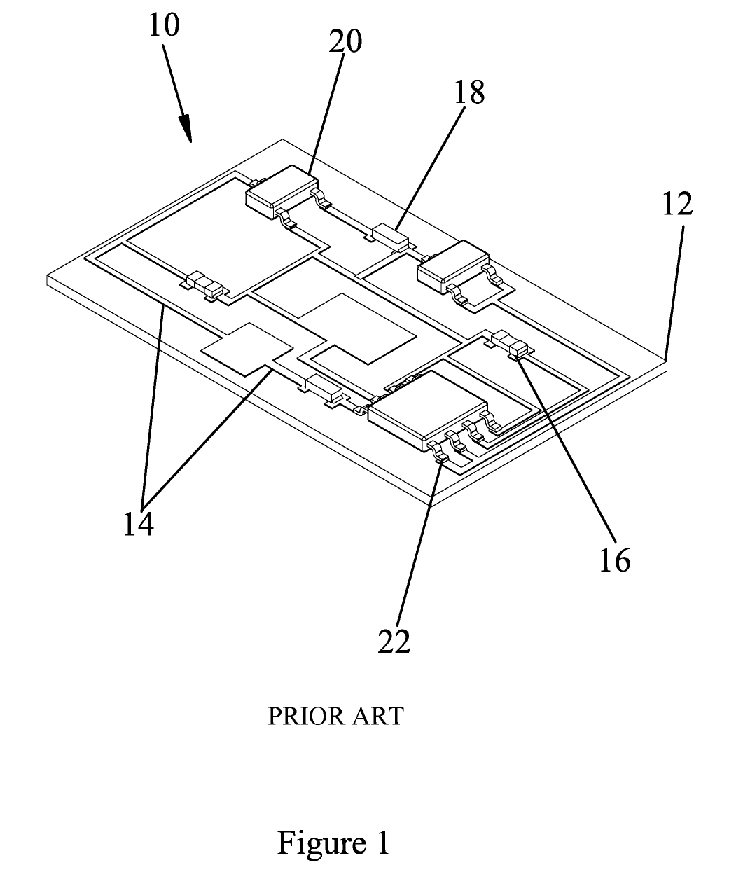

FIG. 1 is a detailed illustration of a perspective view of a prior art circuit board. FIG. 1 shows a standard one prior art circuit board 10. The prior art circuit board includes a printed circuit board 12, printed circuits 14 and components such as resistors 16, capacitors 18, and integrated circuit chips 20. As shown in FIG. 1, the components are attached on one side of the circuit board. The components are typically attached by soldering the contacts 22 of the components to the appropriate printed circuits 14 of the circuit board 12.

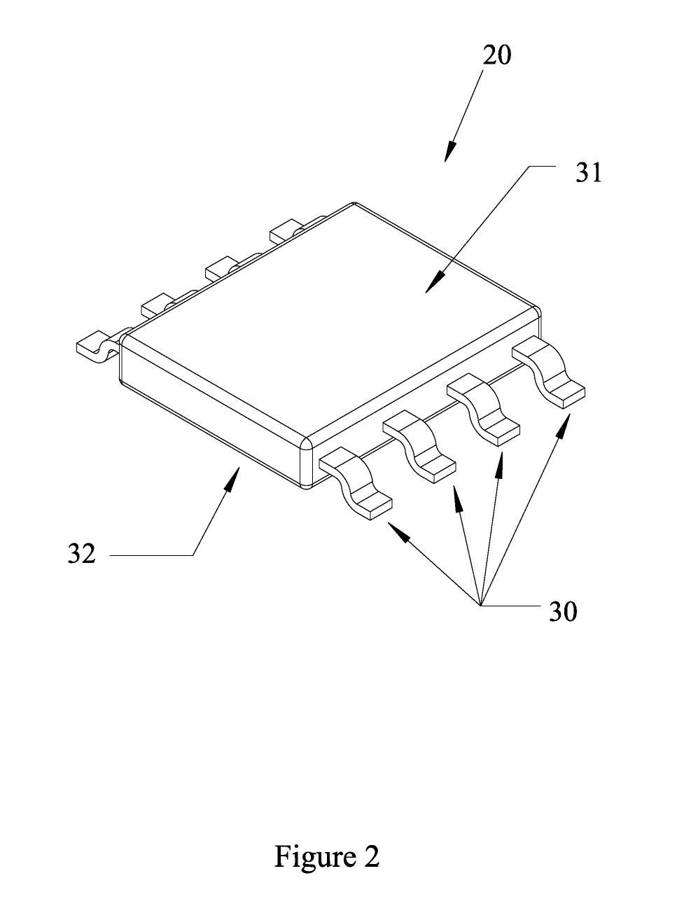

FIG. 2 is a detailed illustration of a perspective view of a circuit board component. FIG. 2 shows component 20, an integrated circuit chip, with top side 31, bottom side 32, and contacts 30.

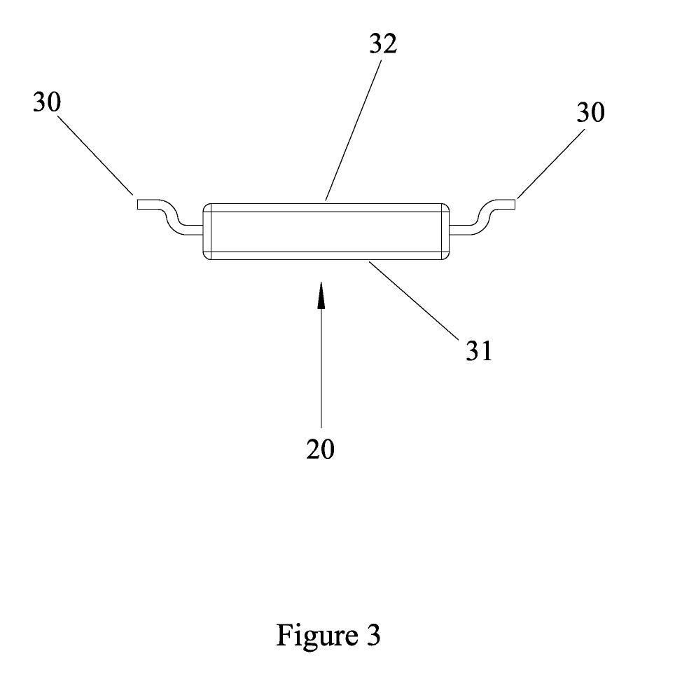

FIG. 3 is a detailed illustration of a side view of an inverted circuit board component. FIG. 2 shows component 20, an integrated circuit chip, inverted so that top side 31 is face down and bottom side 32 is face up. FIG. 2 also shows that when integrated circuit chip 20 is inverted the contacts 30 are positioned to enable connection to a top side of a circuit board as will be shown below.

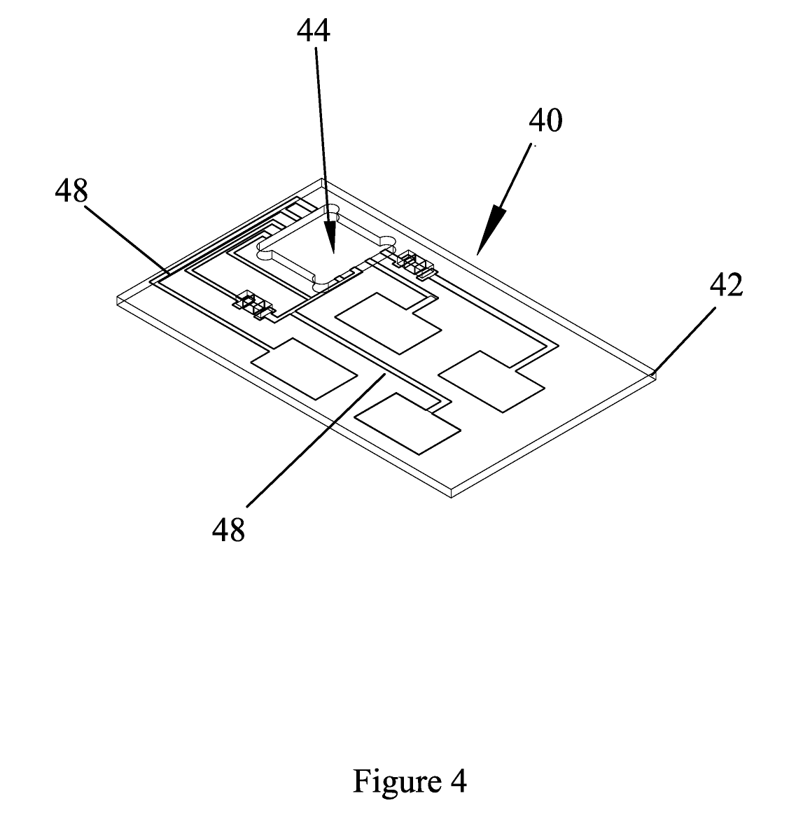

FIG. 4 is a detailed illustration of a perspective view of one embodiment of the present invention and shows a precision clearance hole. The circuit board 40, as shown in FIG. 4, preferably includes printed circuit board 42, printed circuits 48, and a precision clearance hole 44. Preferably precision clearance hole 44 is cut through the entire thickness of the printed circuit board. However, it should be understood that the precision clearance hole 44 may be a notch cut into the printed circuit board 42 that does not go through the entire thickness of the board without deviating from the scope of the invention. Preferably the precision clearance hole is cut such that the edges of the hole are not lined or plated and the edges are not designed to continue the conductive properties of the printed circuits 48 on the surfaces of the of the circuit board 40.

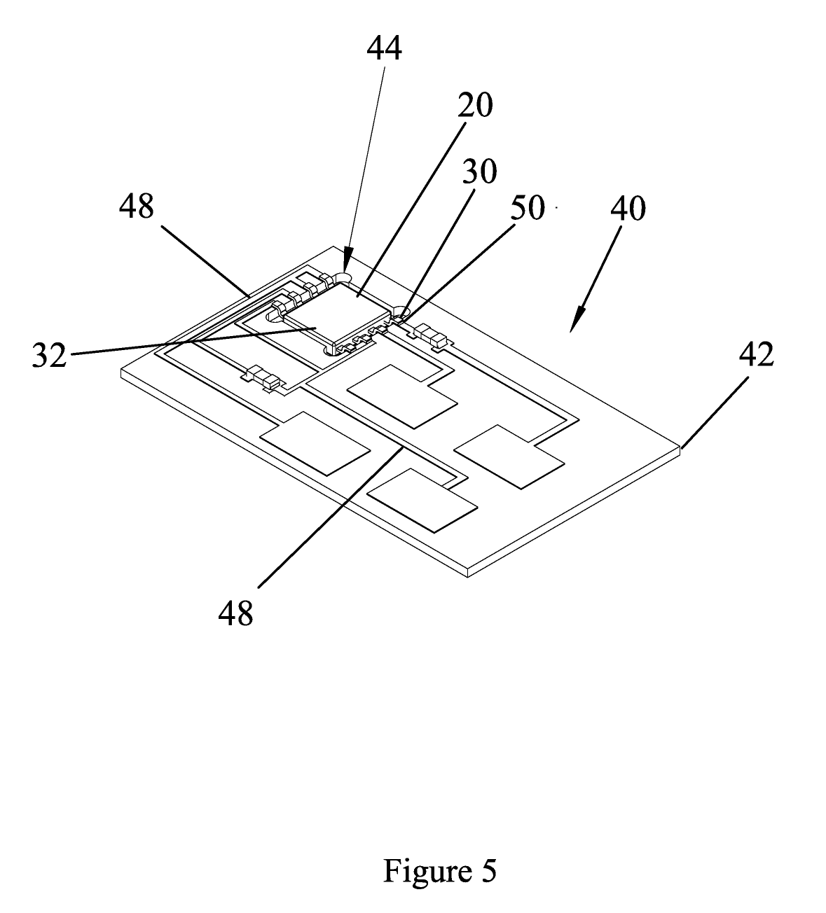

FIG. 5 is a detailed illustration of a perspective view of one embodiment of the present invention and shows a component inserted into a precision clearance hole. FIG. 5 shows that circuit board 40 preferably includes at least printed circuit board 42, printed circuits 48, precision clearance hole 44 and component 20. Component 20 is preferably an integrated circuit chip, but can be any component attached to a circuit board, including but not limited to resistors, capacitors, chips, diodes, and transistors. The component 20 is preferably inverted so that bottom side 32 is upward. The inverted component 20 is inserted into precision clearance hole 44 and the contacts 30 are affixed to the top of printed circuit board 42.

As shown in FIG. 5 the precision clearance hole 44 is preferably cut to specifically accommodate the size and shape of component 20. This accommodation allows the printed circuit board to work with off the shelf components, which significantly reduces the cost of manufacturing. In this case component 20 is an example of a surface mounted integrated circuit chip with L-shaped contacts. The component 20 is inverted so that the body of component 20 fits matingly into precision clearance hole 44 and the L-shaped contacts can attach to the top of the printed circuit board 42. When component 20 is inverted the top of component 20 is inserted first into precision clearance hole 44 and the bulk of the body of component 20 fits into precision clearance hole 44. Once contacts 30 are attached or soldered 50 onto the printed circuit board 42 the bottom side 32 of component 20 is preferably facing in the same direction as the top of the printed circuit board 42. Additionally, if positioned correctly, the surfaces of the printed circuit board 42 and surfaces of component 20 are parallel. Finally, as shown in FIG. 5, the sides of component 20 and the sides of printed circuit board 42 are very close to each other but do not touch.

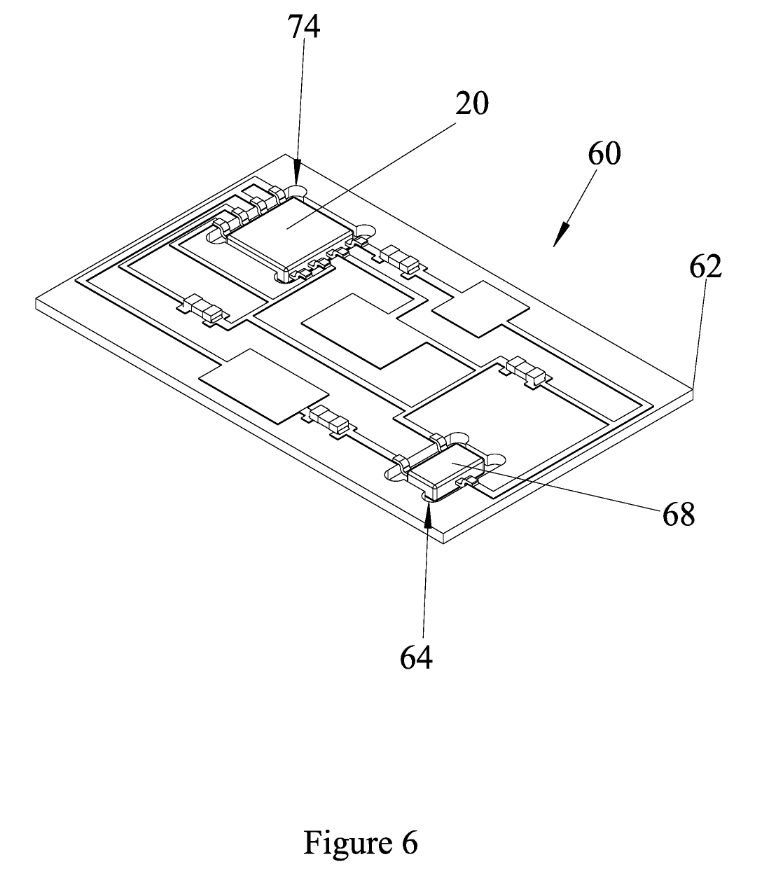

FIG. 6 is a detailed illustration of a perspective view of one embodiment of the present invention and shows two components inserted into two precision clearance holes. FIG. 6 shows how the invention can include more than one precision clearance hole and inserted components. FIG. 6 shows that circuit board 60 may include circuit board 62, precision clearance holes 64 and 74, component 20, and component 68. Components 20 and 68 are inverted and inserted into precision clearance holes 64 and 74.

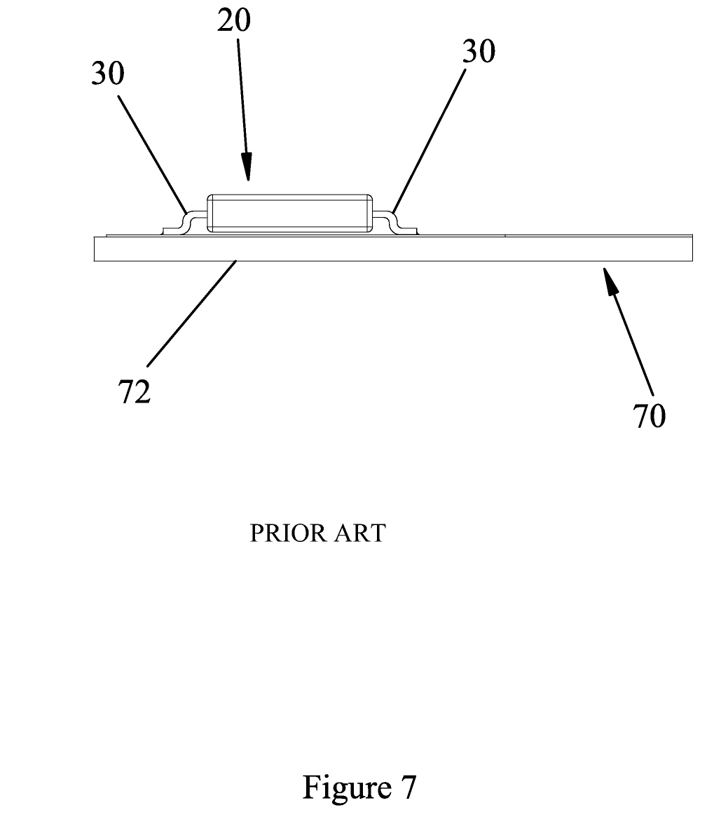

FIG. 7 is a detailed illustration of a side view of a prior art circuit board. FIG. 7 shows a prior art circuit board 70 with printed circuit board 72 and component 20. Component 20 is attached to printed circuit board 72 via contacts 30. FIG. 7 shows how the thickness of circuit board 70 is at least the combination of the thicknesses of component 20 and printed circuit board 72.

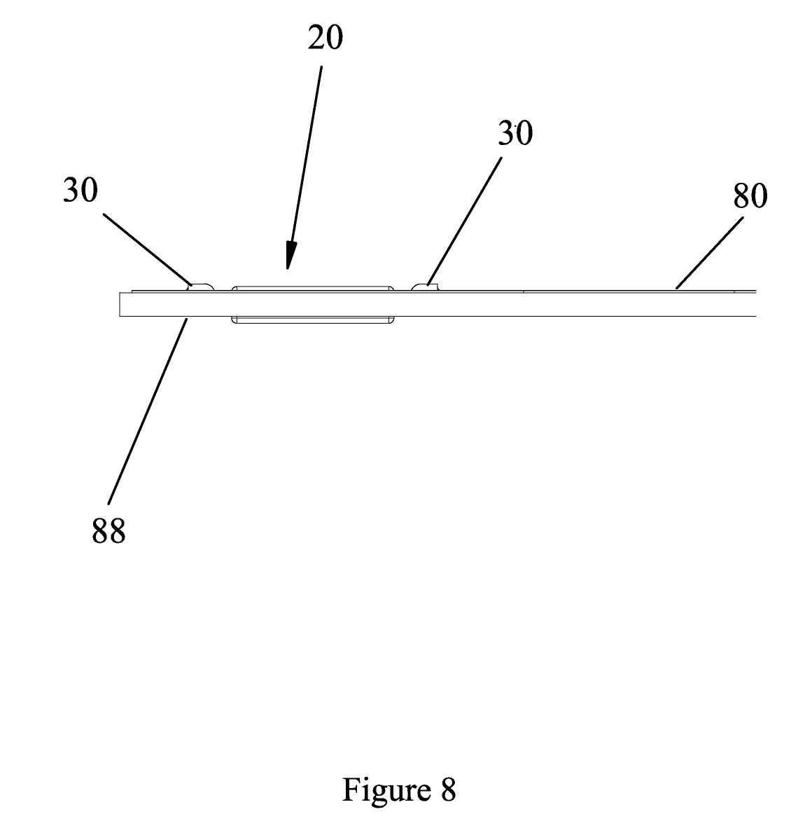

FIG. 8 is a detailed illustration of a side view of one embodiment of the present invention and shows a component inserted into a precision clearance hole. FIG. 7 shows the present invention, circuit board 80 with printed circuit board 88 and component 20. Component 20 is attached to printed circuit board 88 via contacts 30. FIG. 7 shows how the thickness of circuit board 80 is not determined by the combination of the thicknesses of component 20 and printed circuit board 88. Indeed, circuit board 80 is much thinner than circuit board 70 (shown in FIG. 7).

Thus, the invention is a thin space-saving circuit board that can be made with off the shelf circuit board components.

The foregoing description of the preferred embodiment of the invention has been presented for the purposes of illustration and description. While multiple embodiments are disclosed, still other embodiments of the present invention will become apparent to those skilled in the art from the above detailed description, which shows and describes illustrative embodiments of the invention. As will be realized, the invention is capable of modifications in various obvious aspects, all without departing from the spirit and scope of the present invention. Accordingly, the detailed description is to be regarded as illustrative in nature and not restrictive. Also, although not explicitly recited, one or more embodiments of the invention may be practiced in combination or conjunction with one another. Furthermore, the reference or non-reference to a particular embodiment of the invention shall not be interpreted to limit the scope of the invention. It is intended that the scope of the invention not be limited by this detailed description, but by the claims and the equivalents to the claims that are appended hereto.

We claim:

1. A space-saving circuit board comprising:
a circuit board;
a precision clearance hole; and
a component;
wherein said component is comprised of a body and one or more contacts;
wherein said precision clearance hole is cut into said circuit board; and
wherein said body of said component is inserted into said precision clearance hole and said one or more contacts are affixed to said circuit board.

2. The space-saving circuit board of claim 1, wherein a size and a shape of said precision clearance hole corresponds to a size and a shape of said component; and wherein said body of said component fits matingly with said precision clearance hole.

3. The space-saving circuit board of claim 2, wherein said space-saving circuit board is a replacement circuit board for a printer.

4. The space-saving circuit board of claim 2, wherein said component is a surface mounted integrated circuit chip;
wherein said circuit board has a top side and a bottom side;
wherein said surface mounted integrated circuit chip is comprised of a body top side, a body bottom side, and one or more chip contacts;
wherein said surface mounted integrated circuit chip is inverted before being inserted into said precision clearance hole such that said body top side of said surface mounted integrated circuit chip is facing a same direction as and is essentially parallel to a bottom side of said circuit board; and
wherein said chip contacts are affixed to said top side of said circuit board.

5. The space-saving circuit board of claim 1, further comprising:
a plurality of precision clearance holes;
a plurality of components; and
wherein said plurality of components are inserted into said plurality of precision clearance holes.

6. The space-saving circuit board of claim 5, wherein a size and a shape of said plurality of precision clearance holes corresponds to a size and a shape of said plurality of components and wherein said plurality of components fit matingly with said plurality of precision clearance holes.

7. The space-saving circuit board of claim 6, wherein said space-saving circuit board is a replacement circuit board for a printer.

8. A method of constructing a space-saving circuit board, the steps comprising:
providing a circuit board;
providing one or more components;
wherein said one or more components are comprised of a body and one or more contacts;
cutting one or more precision clearance holes into said circuit board such that said one or more components correspond with said one or more precision clearance holes;
inserting said one or more components into said one or more precision clearance holes;
affixing said one or more contacts to said circuit board.

9. The method of constructing a space-saving circuit board of claim 8, wherein said one or more components are one or more surface mounted integrated circuit chips;
wherein said circuit board has a top side and a bottom side;
wherein said one or more surface mounted integrated circuit chips have a body top, side, a body bottom side, and one or more chip contacts;
wherein said chip contacts are on a body bottom side of said one or more surface mounted integrated circuit chips;
wherein said one or more surface mounted integrated circuit chips are inverted before being inserted into said one or more precision clearance holes such that said body top side of said one or more surface mounted integrated circuit chips is facing a same direction as and is essentially parallel to a bottom side of said circuit board; and
wherein said chip contacts are affixed to said top side of said circuit board.
